(19) United States
(12) Patent Application Publication
(10) Pub. No.: US 2019/0056661 A1
(43) Pub. Date: Feb. 21, 2019

(54) PHOTO-IMAGEABLE THIN FILMS WITH HIGH DIELECTRIC STRENGTH

(71) Applicant: Dow Global Technologies LLC, Midland, MI (US)

(72) Inventors: Caroline Woelfle-Gupta, Midland, MI (US); Yuanqiao Rao, Freeport, TX (US)

(21) Appl. No.: 16/079,344

(22) PCT Filed: Mar. 16, 2017
(86) PCT No.: PCT/US2017/022623

§ 371 Date: Aug. 23, 2018

Related U.S. Application Data
(60) Provisional application No. 62/312,624, filed on Mar. 24, 2016.

(51) Int. Cl. G03F 7/023; G03F 7/022; G03F 7/004

(52) U.S. Cl. CPC G03F 7/0236; G03F 7/0047; G03F 7/0226

(57) ABSTRACT

A formulation for preparing a photo-imagable film; said formulation comprising: (a) a positive photoresist comprising a cresol novolac resin and a diazonaphthoquinone inhibitor; and (b) functionalized zirconium oxide or barium titanate nanoparticles having a molar ratio of zirconium oxide or barium titanate to ligand from 0.2 to 20.

### FIELD OF THE INVENTION

The present invention relates to a photo-imagable thin film with high dielectric strength.

### BACKGROUND OF THE INVENTION

High dielectric strength thin films are of high interest for applications such as embedded capacitors, TFT passivation layers and gate dielectrics, in order to further miniaturize microelectronic components. One approach for obtaining a photo-imagable high dielectric strength thin film is to incorporate high dielectric constant nanoparticles in a photoresist. US2005/0256240 discloses composite thin films based on polymers such as epoxy, polyolefin, ethylene propylene rubber and polyetherimide which contain nanoparticles of metal oxides as well as nanoparticles coated with coupling agents having high dielectric strength. However, this reference does not disclose the composites used in the present invention.

### SUMMARY OF THE INVENTION

The present invention provides a formulation for preparing a photo-imagable film; said formulation comprising: (a) a positive photoresist comprising a cresol novolac resin and a diazonaphthoquinone inhibitor; and (b) functionalized zirconium oxide or barium titanate nanoparticles having a molar ratio of zirconium oxide or barium titanate to ligand from 0.2 to 20.

### DETAILED DESCRIPTION OF THE INVENTION

Percentages are weight percentages (wt %) and temperatures are in ° C., unless specified otherwise. Operations were performed at room temperature (20-25V), unless specified otherwise. The term “nanoparticles” refers to particles having a diameter from 1 to 100 nm; i.e., at least 90% of the particles are in the indicated size range and the maximum peak height of the particle size distribution is within the range. Preferably, nanoparticles have an average diameter 75 nm or less; preferably 50 nm or less; preferably 25 nm or less; preferably 10 nm or less; preferably 7 nm or less. Preferably, the average diameter of the nanoparticles is 0.3 nm or more; preferably 1 nm or more. Particle sizes are determined by Dynamic Light Scattering (DLS). Preferably the breadth of the distribution of diameters of zirconia particles, as characterized by breadth parameter BP=(N75−N25), is 4 nm or less; more preferably 3 nm or less; more preferably 2 nm or less. Preferably the breadth of the distribution of diameters of zirconia particles, as characterized by BP=(N75−N25), is 0.01 or more. It is useful to consider the quotient W as follows:

W=(N75−N25)/Dm

where Dm is the number-average diameter. Preferably W is 1.0 or less; more preferably 0.8 or less; more preferably 0.6 or less; more preferably 0.5 or less; more preferably 0.4 or less. Preferably W is 0.05 or more.

Preferably, the functionalized nanoparticles comprise zirconium oxide or barium titanate and one or more ligands, preferably ligands which have alkyl, heteroalkyl (e.g., poly(ethylene oxide)) or aryl groups having polar functionality; preferably phosphoric acid, carboxylic acid, alcohol, trichlorosilane, trialkoxysilane or mixed chloro/alkoxy silanes; preferably carboxylic acid. It is believed that the polar functionality bonds to the surface of the nanoparticle. Preferably, ligands have from one to twenty-five non-hydrogen atoms, preferably one to twenty, preferably three to fifteen. Preferably, ligands comprise carbon, hydrogen and additional elements selected from the group consisting of oxygen, sulfur, nitrogen and silicon. Preferably alkyl groups are from C₁-C₁₈, preferably C₂-C₁₂, preferably C₃-C₈. Preferably, aryl groups are from C₆-C₁₂. Alkyl or aryl groups may be further functionalized with isocyanate, mercapto, glycidoxy or (meth)acryloyloxy groups. Preferably, alloxy groups are from C₁-C₄, preferably methyl or ethyl. Among organosilanes, some suitable compounds are alkyltrialkoxysilanes, alloxy(polyalkyleneoxy)alkykrialkoxysilanes, substituted-alkyltrialkoxysilanes, phenybialloxysilanes, and mixtures thereof. For example, some suitable oranosilanes are n-prupyltrimethoxysilane, n-propyltriethoxysilane, n-octyltrimethoxysilane, n-octyltriethoxysilane, phenyltrimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-isocyanatopropyltriethoxysilane, 3-isocyanatopropyltrimethoxysilane, glycidoxypropyltrimethoxysilane, and mixtures thereof.

Among organoalcohols, preferred are alcohols or mixtures of alcohols of the formula R¹⁰OH, where R¹⁰ is an aliphatic group, an atomatic-substituted alkyl group, an aromatic group, or an alkylalloxy group. More preferred organoalcohols at ethanol, propanol, butanol, hexanol, heptanol, octanol, dodecyl alcohol, octadecanol, benzyl alcohol, phenol, oleyl alcohol, triethylene glycol monomethyl ether, and mixtures thereof. Among organocarboxylic acids, preferred are carboxylic acids of formula R¹¹COOH, where R¹¹ is an aliphatic group, an aromatic group, a polyalkoxy group, or a mixture thereof. Among organocarboxylic acids in which R¹¹ is an aliphatic group, preferred aliphatic groups an methyl, propyl, octyl, oleyl, and mixtures thereof. Among organocarboxylic acids in which R¹¹ is an aromatic group, the preferred aromatic group is C₆H₅. Preferably R¹¹ is a polyalkoxy group. When R¹¹ is a polyalkoxy group, R¹¹ is a linear string of alloxy units, where the alkyl group in each unit may be the same or different from the alkyl groups in other units. Among organocarboxylic acids in which R¹¹ is a polyalkoxy group, preferred alloxy units are methoxy, ethoxy, and combinations thereof. Functionalized nanoparticles are described, e.g., in US2013/0221279.

Especially preferred ligands include phosphonic acid ligands, preferably those having alkyl or heteroalkyl substituent groups. Preferably, heteroalkyl groups are based on ethylene oxide oligomers, preferably with a C₁-C₄ alkyl ether on one end, preferably methyl. Preferably, heteroalkyl groups contain from one to four polymerized units of ethylene oxide, preferably one to three. Preferably, heteroalkyl groups are attached to phosphorus via an ethyl linker, i.e., RO(CH₂CH₂O)ₙCH₂CH₂—. Preferably, the molar ratio of metal oxide to ligand is at least 0.25, preferably at least 0.3, preferably at least 0.35, preferably at least 0.4, preferably at least 0.5, preferably at least 0.6; preferably no greater than 15, preferably no greater than 10, preferably no greater than 7, preferably no greater than 5. For zirconium oxide the preferred molar ratio of zirconium oxide to ligand is at least 0.25, preferably at least 0.3, preferably at least 0.35, preferably at least 0.4; preferably no greater than 10, preferably no greater than 7, preferably no greater than 5, preferably no greater than 3. For barium titanate the preferred molar ratio of barium titanate to ligand is at least 0.5, preferably at least 0.55, preferably at least 0.6, preferably at least 0.65, preferably at least 0.7; preferably no greater than 17, preferably no greater than 14, preferably no greater than 11, preferably no greater than 8, preferably no greater than 6.

Preferably, the amount of functionalized nanoparticles in the formulation (calculated on a solids basis for the entire formulation) is from 50 to 95 wt %; preferably at least 60 wt %, preferably at least 70 wt %, preferably at least 80 wt %, preferably at least 90 wt %; preferably no greater than 90 wt %.

A diazonaphthoquinone inhibitor provides sensitivity to ultraviolet light. After exposure to ultraviolet light, diazonaphthoquinone inhibitor inhibits dissolution of the photoresist film. The diazonaphthoquinone inhibitor may be made from a diazonaphthoquinone having one or more sulfonyl chloride substituent groups and which is allowed to react with an aromatic alcohol species, e.g., cumylphenol, 1,2,3-trihydroxybenzophenone, p-cresol timer or the cresol novolak resin itself.

Preferably, the cresol novolac resin has epoxy functionality from 2 to 10, preferably at least 3; preferably no greater than 8, preferably no greater than 6. Preferably, the cresol novolac resin comprises polymerized units of cresols, formaldehyde and epichlorohydrin.

Preferably, the film thickness is at least 50 nm, preferably at least 100 nm, preferably at least 500 nm, preferably at least 1000 nm; preferably no greater than 3000 nm, preferably no greater than 2000 nm, preferably no greater than 1500 nm. Preferably, the formulation is coated onto standard silicon wafers or Indium-Tin Oxide (ITO) coated glass slides.

### EXAMPLES

### Example 1

1 Experimental

### 1.1 Materials

Zirconium oxide (ZrO₂) nanoparticles (2-5 nm in primary particle size, 5.89 g/cm³ in density) purchased from SkySpring nanomaterials Inc, as well as barium titanate (BaTiO₃) nanoparticles (<100 nm in primary particle size, 6.08 g/cm³ in density) purchased from Sigma-Aldrich were utilized. A phosphonic acid ligand, 2-{2-2-_2-Methoxy-ethoxy_-ethoxy-ethoxy}-ethyl phosphonic acid was purchased from Sikemia. Ethanol, tetrahyclrofuran, and hexanes were purchased from Sigma-Aldrich. The SPR-220 Mine photoresist was purchased from MicroChem. The developer MF-26A was provided by the Dow Electronic Materials group.

### 1.2 Nanoparticle Functionalization

Both types of nanoparticles were functionalized using a nanoparticle to ligand weight ratio of 1.25 (molar ratio 0.43 for zirconium oxide, 0.82 for barium titanate), via sonication for 4 h and further refluxing under inert atmosphere at 80° C. for 1 h in an (95%/5%) ethanol/water solution. The solutions obtained were then separated into two batches for each type of nanoparticle. One batch was left to sit for two weeks undisturbed. After two weeks the supernatant was retrieved and two solutions containing respectively functionalized barium titanate with excess ligand and functionalized zirconium oxide with excess ligand were obtained.
For the second batch, in the case of the barium titanate nanoparticles, four centrifugation/rinsing steps were performed with ethanol in order to remove the excess ligand. In the case of the zirconium oxide nanoparticles, an additional precipitation step had to be performed to remove the particles from solution before they could be centrifuged and rinsed four times. This was done by using a 1:3 volume ratio solution of THF and hexanes, and a 1 to 7 ratio of nanoparticle solution to solvent solution. In each case, the rinsed nanoparticles were then left to sit undisturbed in a hood for one week to slowly evaporate the remaining ethanol.

### 1.3 Functionalized Nanoparticles Characterization

The functionalized nanoparticles were characterized via solid state phosphorus-31 NMR. The percentage of ligand present on the functionalized nanoparticles without excess ligand was determined via TGA (Model Q5000IR) with a temperature gradient of 10° C./min.

### 1.4 Thin Films

The dried functionalized barium titanate and zirconium oxide nanoparticles were each redispersed in a small amount of ethyl lactate to be able to further mix them with the positive I-line photoresist SPR-220 at different ratios. The functionalized barium titanate solutions with excess ligand, as well as the functionalized zirconium oxide solutions with excess ligand were mixed with the photoresist at different ratios as well. The different solutions obtained were left to stir overnight and further processed into thin films on ITO wafers, as well as silicon wafers via a spin coater with a spin speed of 1500 rpm for 2 min. The weight percentage of nanoparticles present in solution was determined via TGA (Model Q5000IR), and the percentages of nanoparticles present in the fabricated thin film were then recalculated based on the numbers obtained, and the solids content of the photoresist determined via TGA as well.

### 1.5 Dielectric Strength Measurements

Four 50 nm thick gold electrodes 3 mm in diameter were deposited on each nanoparticle-photoresist thin films. The breakdown voltage was determined by measuring the current as the voltage applied to the electrodes was increased by 25 V every 5 s up to 1,000 V. The current was recorded every 0.25 s, and the last four measurements were averaged to give the current at the desired voltage. The first four seconds of data was discarded due to the presence of a buffer implemented to allow the instrument to survive up to 1000V.

### 1.6 Dielectric Constant Measurements

Four 50 nm thick gold electrodes 3 mm in diameter were deposited on each nanoparticle-photoresist thin films. The ITO was contacted with an alligator clip, and the gold electrodes with a gold wire to be able to apply a frequency sweep to the sample. The capacitance was measured for each sample, and the dielectric constant determined via Equation 1 with C being the capacitance, εᵣ the dielectric constant, co the vacuum dielectric permittivity, A the area of the electrode, and d the thickness of the film.

C=εᵣε₀·A/d Equation 1

### 1.7 Thickness of the Films

The coatings were scratched with a razor blade using different down forces to make trenches. Profilometry was performed on a Dektak 150 stylus profilometer across the trench where the ITO substrate was exposed. Thicknesses were recorded on the flat areas of the profile generated with a scan length of 500 um, a scan resolution of 0.167 μm per sample, a stylus radius of 2.5 μm, a stylus force of 1 mg, and with the filter cutoff in the OFF mode.

### 1.8 Photoimageability

Photoimageability conditions are summarized in Table 1. The films were exposed to UV radiation via the use of an Oriel Research arc lamp source housing a 1000 W mercury lamp fitted with a dichroic beam turning mirror designed for high reflectance and polarization insensitivity over a 350 to 450 primary spectral range. The developer used was MF-26A based on tetramethyl ammonium hydroxide. After post bake, the coated wafers were dipped into a petri dish containing MF-26A for 2, 4, and 6 min. Thickness of the films after each dipping time was determined via an M-2000 Woollam spectroscopic ellipsometer.

TABLE 1
Photoimageability conditions

| UV Exposure | Hold Time | Post Bake @ 115° C. |
|---|---|---|
| 380 mJ/cm² | 35 min | 2 min |

### 1.9 Roughness of the Films

The samples were mounted on the stage using double-sided carbon tape and then blown-cleaned with a duster for AFM analysis. AFM images were captured at ambient temperature by using a Veeco (now Bruker) Icon AFM system with a Mikromasch probe. The probe has a spring constant of 40 N/m and a resonant frequency in the vicinity of 170 kHz. An imaging frequency of 0.5-2 Hz was used with a set point ratio of 0.8.

2 Results

### 2.1 Dielectric Strength of the Thin Films

Table 2 lists the dielectric strength of the thin films produced as a function of the weight percent of nanoparticles present in the thin films. The data clearly indicate that a dielectric strength of up to 428V/μm could be obtained for the composite photoresist-nanoparticle thin films based on the zirconium oxide nanoparticles and the barium titanate nanoparticles functionalized with the phosphonic acid ligand with excess ligand maintained in the nanoparticle solution mixed with the photoresist (Type I thin films). Additionally, in both cases the dielectric strength significantly increased with the amount of nanoparticles present in solution. The dielectric strength was significantly lower for the composite photoresist-nanoparticle thin films based on the zirconium oxide nanoparticles and the barium titanate nanoparticles functionalized with the phosphonic acid ligand without excess ligand maintained in the nanoparticle solution mixed with the photoresist (Type II thin films). The difference observed could be attributed to the higher amount of ligand present in the Type I thin films, leading to a more compact interface between the nanoparticles and the photoresist, as well as the presence of a passivation layer reducing the generation of charge carriers that can increase conduction within the films. The additional amount of ligand present, as well as the lower initial particle size of the nanoparticles present in the solution mixed with the photoresist lead to better dispersed nanoparticles for the type I thin films, as well as a higher amount of interfaces leading to an increased influence of the passivation layer. A more compact interface between the nanoparticle and the photoresist lead as well to a reduced number of pores and voids, which can be responsible for a decrease in the dielectric strength for nanocomposite thin films where the interface between the nanoparticles and the photoresist is loose. The dielectric strength obtained for the Type II thin films was around 100V/um for the thin films based on barium titanate, and between 70 and 75V/μm for the thin films based on zirconium oxide. Tables 3 and 4 list the dielectric constant and energy storage density, respectively, for the same films

TABLE 2
Dielectric strength of the different thin films produced

| | | Wt. % | Dielectric | |
|---|---|---|---|---|
| Sam- | | of nano- | strength | |
| ple | Type of nanoparticle | particles | (V/um) | Stdev |
| 1 | Funct. ZrO₂ | 51.16 | 76.81 | 1.22 |
| 2 | Funct. ZrO₂ | 39.94 | 72.12 | 27.07 |
| 3 | Funct. ZrO₂ + excess ligand | 45.39 | 369.27 | 76.82 |
| 4 | Funct. ZrO₂ + excess ligand | 34.39 | 218.39 | 82.84 |
| 5 | Funct ZrO₂ + excess ligand | 58.73 | 427.76 | 78.22 |
| 6 | Funct ZrO₂ + excess ligand | 30.85 | 210.78 | 38.62 |
| 7 | Funct BaTiO₃ + excess ligand | 52.06 | 292.83 | 137.98 |
| 8 | Funct BaTiO₃ + excess ligand | 39.27 | 428.82 | 33.45 |
| 9 | Funct BaTiO₃ + excess ligand | 40.24 | 379.10 | 13.52 |
| 10 | Funct BaTiO₃ + excess ligand | 36.74 | 206.14 | 39.15 |
| 11 | Funct BaTiO₃ + excess ligand | 32.68 | 147.73 | 61.79 |
| SPR- | | 0.00 | 26.8 | 0 |
| 220 | | | | |

TABLE 3
Dielectric constant of the different thin films produced

| | | Wt. % | | |
|---|---|---|---|---|
| Sam- | | of nano- | Dielectric | |
| ple | Type of nanoparticle | particles | constant | Stdev |
| 1 | Funct. ZrO₂ | 51.16 | 5.56 | 0.091182 |
| 2 | Funct. ZrO₂ | 39.94 | 3.17 | 0 |
| 3 | Funct. ZrO₂ + excess ligand | 45.39 | 3.83 | 0 |
| 4 | Funct. ZrO₂ + excess ligand | 34.39 | 4.08 | 0.168075 |
| 5 | Funct ZrO₂ + excess ligand | 58.73 | 4.19 | 0.29921 |
| 6 | Funct ZrO₂ + excess ligand | 30.85 | 4.39 | 0.235814 |
| 7 | Funct BaTiO₃ + excess ligand | 52.06 | 4.26 | 0 |
| 8 | Funct BaTiO₃ + excess ligand | 39.27 | 4.25 | 0.296916 |
| 9 | Funct BaTiO₃ + excess ligand | 40.24 | 4.35 | 0.177544 |
| 10 | Funct BaTiO₃ + excess ligand | 36.74 | 4.16 | 0.128267 |
| 11 | Funct BaTiO₃ + excess ligand | 32.68 | 4.67 | 0.023827 |
| SPR- | | 0.00 | 4.14 | 0 |
| 220 | | | | |

TABLE 4
Energy storage density of the different thin films produced

| | | Wt. % of | | |
|---|---|---|---|---|
| | | nano- | Umax | |
| Sample | Type of nanoparticle | particles | (J/cm³) | Stdev |
| 1 | Funct. ZrO₂ | 51.16 | 0.1453 | 0.0040 |
| 2 | Funct. ZrO₂ | 39.94 | 0.0730 | 0.0388 |
| 3 | Funct. ZrO₂ + excess ligand | 45.39 | 2.3143 | 0.6809 |
| 4 | Funct. ZrO₂ + excess ligand | 34.39 | 0.8621 | 0.4638 |
| 5 | Funct ZrO₂ + excess ligand | 58.73 | 3.3928 | 0.9103 |
| 6 | Funct ZrO₂ + excess ligand | 30.85 | 0.8627 | 0.2283 |
| 7 | Funct BaTiO₃ + excess ligand | 52.06 | 1.6171 | 1.0776 |
| 8 | Funct BaTiO₃ + excess ligand | 39.27 | 3.4621 | 0.4519 |
| 9 | Funct BaTiO₃ + excess ligand | 40.24 | 2.7676 | 0.1796 |
| 10 | Funct BaTiO₃ + excess ligand | 36.74 | 0.7827 | 0.2116 |
| 11 | Funct BaTiO₃ + excess ligand | 32.68 | 0.4512 | 0.2669 |
| SPR-220 | | 0.00 | 0.0127 | 0.0000 |

### 2.2 Photoimageability

Table 5 represents the ratio of the thickness of the film after exposure conditions (detailed in Table 1), and a 2 min soak time in the developer MF-26A to the initial film thickness as a function of the volume percent of nanoparticles present in the film. It could be observed that all the films prepared were completely removed at exposure conditions and soak time in the developer similar to the base photoresist.

TABLE 5

| | | | Thickness of the | Thickness of the film after |
|---|---|---|---|---|
| | | Wt. % of | film before | exposure and 2 min in |
| Sample | Type of nanoparticles | nanoparticles | exposure (nm) | developer (nm) |
| 1 | Funct. ZrO₂ | 51.16 | 2297.74 | 2.04 |
| 2 | Funct. ZrO₂ | 39.94 | 7016.96 | 2.99 |
| 3 | Funct. ZrO₂ + excess ligand | 45.39 | 1174.75 | 2.37 |
| 4 | Funct. ZrO₂ + excess ligand | 34.39 | 2408.93 | 2.52 |
| 5 | Funct. ZrO₂ + excess ligand | 58.73 | 413.19 | 2.20 |
| 6 | Funct. ZrO₂ + excess ligand | 30.85 | 4189.65 | 3.23 |
| 7 | Funct. BaTiO₃ + excess ligand | 52.06 | 557.54 | 2.50 |
| 8 | Funct. BaTiO₃ + excess ligand | 39.27 | 1154.6 | 2.50 |
| 9 | Funct. BaTiO₃ + excess ligand | 40.24 | 2349.73 | 2.42 |
| 10 | Funct. BaTiO₃ + excess ligand | 36.74 | 3402.79 | 1.93 |
| 11 | Funct. BaTiO₃ + excess ligand | 32.68 | 3783.45 | 2.50 |

### 2.1 Surface Roughness of the Thin Films

Table 6 summarizes the Root Mean Square (RMS) roughness of the different films produced. It could be noticed that the surface roughness of films based on solutions of functionalized nanoparticles with excess ligand remaining in the solution mixed with the photoresist had significantly lower surface roughness than films based on solutions of functionalized nanoparticles without excess ligand remaining in solution mixed with the photoresist. This could be attributed to the better dispersion of the nanoparticles in the films for the former case. Different thin films (Sample 6, Sample 9, sample 10, and Sample 11) containing functionalized nanoparticles with excess ligand had a surface roughness as low as the surface roughness of the control. Additionally, for thin films made of functionalized ZrO₂ or BaTiO₃ without excess ligand remaining in solution, it could be noticed that the surface roughness was lower for the films based on BaTiO₃. This could be attributed to the lower particle size of the ZrO₂ nanoparticles inducing aggregation of the nanoparticles in solution.

TABLE 6
Root Mean Square (RMS) roughness
of the different films produced.

| | | Excess | | | |
|---|---|---|---|---|---|
| | | ligand | Wt. % of | Mean Sq. | |
| Sample | Nanoparticle type | present | nanoparticles | (nm) | Stdev |
| 1 | ZrO₂ | No | 51.16 | 10.3 | 0.4 |
| 2 | ZrO₂ | No | 39.94 | 12.9 | 0.5 |
| 3 | ZrO₂ | Yes | 45.39 | 1 | 0.2 |
| 4 | ZrO₂ | Yes | 34.39 | 0.3 | 0 |
| 5 | ZrO₂ | Yes | 58.73 | 1.1 | 1 |
| 6 | ZrO₂ | Yes | 30.85 | 0.2 | 0 |
| 7 | BaTiO₃ | Yes | 52.06 | 0.3 | 0 |
| 8 | BaTiO₃ | Yes | 39.27 | 0.3 | 0 |
| 9 | BaTiO₃ | Yes | 40.24 | 0.2 | 0 |
| 10 | BaTiO₃ | Yes | 36.74 | 0.2 | 0 |
| 11 | BaTiO₃ | Yes | 32.68 | 0.2 | 0 |
| SPR-220 | | | 0 | 0.2 | 0 |

1. A formulation for preparing a photo-imagable film; said formulation comprising: (a) a positive photoresist comprising a cresol novolac resin and a diazonaphthoquinone inhibitor; and (b) functionalized zirconium oxide or barium titanate nanoparticles having a molar ratio of zirconium oxide or barium titanate to ligand from 0.2 to 20.

2. The formulation of claim 1 in which the functionalized zirconium oxide or barium titanate nanoparticles have an average diameter from 0.3 nm to 50 nm.

3. The formulation of claim 2 in which the functionalized zirconium oxide nanoparticles comprise ligands which have phosphonic acid functionality.

4. The formulation of claim 3 in which the ligands have from three to fifteen non-hydrogen atoms.

5. The formulation of claim 4 in which the cresol novolac resin has epoxy functionality from 2 to 10.

6. The formulation of claim 5 in which the amount of functionalized nanoparticles in the formulation, calculated on a solids basis for the entire formulation, is from 50 to 95 wt %.

7. The formulation of claim 6 in which the cresol novolac resin comprises polymerized units of cresols, formaldehyde and epichlorohydrin.

8. The formulation of claim 7 in which the molar ratio of zirconium oxide or barium titanate to ligand is from 0.25 to 10.
